(19) United States
(12) Patent Application Publication
(10) Pub. No.: US 2025/0165656 A1
(43) Pub. Date: May 22, 2025

(54) GPU-ACCELERATED AND MEMORY-INDEPENDENT LAYOUT GENERATION FOR LARGE-SCALE METAMATERIALS AND METADEVICES

(71) Applicant: The Regents of the University of California, Oakland, CA (US)

(72) Inventors: Abdoulaye Ndao, San Diego, CA (US); Sina Moayed Baharlou, Boston, MA (US); Saeed Hemayat, Boston, MA (US)

(21) Appl. No.: 18/954,332

(22) Filed: Nov. 20, 2024

Related U.S. Application Data
(60) Provisional application No. 63/601,199, filed on Nov. 20, 2023.

(51) Int. Cl. G06F 30/10

(52) U.S. Cl. CPC G06F 30/10

(57) ABSTRACT

A framework for generating a large-scale or unbound graphics design system file is disclosed. In one example aspect, the framework comprises receiving a target layout of the GDSII file, wherein the target layout includes multiple unit cells that each have a geometric shape and oriented at an angle. Upon receiving the target layout, the target layout is divided into blocks of equal size. Within each block, a position, rotation, and scaling of the geometric shapes is calculated. The shapes are generated within each block using matrix multiplication of transformation matrix and unit cell vectors, and the shapes are converted into a GDSII file format.

### CROSS-REFERENCE TO RELATED APPLICATIONS

This patent document claims priority to and benefits of U.S. Provisional Application No. 63/601,199, titled “GPU-ACCELERATED AND MEMORY-INDEPENDENT LAYOUT GENERATION FOR LARGE-SCALE META DEVICES,” and filed on Nov. 20, 2023. The entire contents of the before-mentioned patent application are incorporated by reference as part of the disclosure of this patent document.

### TECHNICAL FIELD

The present disclosure relates to a framework for a fully parallel, efficient, and memory-independent generation of graphic design system II (GDSII) files for arbitrarily large-scale metasurfaces.

### BACKGROUND

Metamaterials are composite materials that are designed and manufactured artificially. By manipulating arrangement of atoms into specific geometries, metamaterials can be engineered to have properties and capabilities that are not possible with naturally occurring materials. Among the most sought-after properties of metamaterials is the negative index of refraction of light and other radiation. Metamaterials offer the potential to precisely control the path of light in a material. Such functionality, however, requires multiple stacks of material layers, which can lead to extensive losses and challenges in nanofabrication.

Metasurfaces are thin-films composed of individual elements that have been developed to overcome the obstacles confronted by metamaterials. In electromagnetic theory, metasurfaces modulate the behaviors of electromagnetic waves through specific boundary conditions rather than constitutive parameters in three-dimensional (3D) space.

### SUMMARY

Disclosed are methods, systems, and computing components for generating a large-scale or unbounded graphic design system II (GDSII) file. In some aspects, a computer-implemented method includes receiving, at a computing device comprising a processor and a memory, a target layout of a GDSII file, wherein the target layout includes multiple unit cells that each have a geometric shape and oriented at an angle; upon receiving the target layout, dividing the target layout into blocks of equal size and/or unequal size; for each block, calculating the position, rotation, and/or scaling of a geometric shape or shapes associated with each block; generating one or more shapes associated with each block using matrix multiplication of one or more transformation matrices and one or more unit cell vectors; and converting the generated the one or more shapes into a GDSII file format.

### BRIEF DESCRIPTION OF THE DRAWINGS

FIG. 1A shows a diagram illustrating an example embodiment of the ParallelGDS framework, in accordance with the disclosed technology.

FIG. 1B shows a diagram depicting an example embodiment of a method in accordance with the ParallelGDS framework of FIG. 1A.

FIG. 2 illustrates various aspects of the two different metasurfaces according to embodiments of the disclosed technology.

FIG. 3 illustrates a process of generating a large-scale GDSII file using the disclosed ParallelGDS framework.

FIG. 4 illustrates comparison of the required memory and generation time of ParallelGDS against GDSPy, GDSPk, and LUMERICAL's polystencil for various metasurfaces.

FIG. 5 illustrates comparison of the required memory and generation time against ParallelGDS against GDSPy and GDSTk while varying the number of vertices.

FIG. 6 illustrates the performance comparison of the disclosed framework against GDSPy and GDSTk on a low-end computer.

FIG. 7 is a flowchart representation of a method for generating a layout using the disclosed ParallelGDS framework.

FIG. 8 shows a diagram of an example embodiment of a data processing unit of a computer device operable to implement the disclosed methods, computer program products, and computing products in accordance with the present technology.

### DETAILED DESCRIPTION

The miniaturization of optical devices to the micro- and nanoscale regimes has experienced an ever-increasing demand in both fundamental science and industry over the past two decades. Recently, metasurfaces have emerged as an ideal platform due to the unprecedented ability to locally modify the properties of incident light at the nanoscale. Metasurfaces are ultrathin optical elements that employ an array of nanostructures called meta-atoms, which collectively control the incident light's amplitude, phase, and polarization. The optical properties of such metasurfaces can be modulated across various wavelengths by carefully designing the meta-atoms. In recent years, a variety of optical devices, including metalenses, structured light projection, beam splitters and combiners, meta-power-limiters, carpet cloaking, holograms, and sensing have been accomplished using both dielectric and plasmonic metasurfaces.

Presently, metasurface designers utilize conventional computing resources and approaches. For example, designers may use various conventional design strategies and numerical methods (e.g., Finite-difference Time-domain (FDTD), Finite Element Method (FEM), Rigorous Coupled Wave Analysis (RCWA), or other) to first find the optimal design for each unit cell (of meta-atoms), e.g., which can be based on the application and the specific properties of the metamaterial (e.g., optical properties, such as phase, intensity, or polarization) that must be manipulated at the nanoscale using the metasurface. Consequently, the whole metasurface (e.g., often comprised of millions to billions of meta-atoms) is designed by placing each individual meta-atom in a pre-determined location, with certain sizes, or certain rotation angles, which can require enormous amounts of computing resources to perform. Once the design is finalized, and its results are verified using simulation software program(s), a layout file containing all geometrical properties of the meta-atoms is created to represent its geometric shape as an input for the fabrication machines (such as Electron Beam Lithography (EBL)). Currently, designers commonly use existing tools like GDSpy, GDStk, LUMERICAL Polystencil, etc. for layout generation. However, these tools may be restrictive for large scale metasurface designs; and for larger metasurfaces that are possible to design using these tools, these tools operate at relatively slow speeds, which is likely based on their processing approaches.

Typically, metasurfaces span a footprint of diameters on the order of 50-500 μm. However, various practical applications require devices of millimeter to centimeter sizes. These applications include medical devices, high-resolution microscopy, wearable devices, virtual and augmented reality (VR and AR), single-atom trapping, large field of view (FOV) transmission-type eyepieces, fingerprint imaging, metasurface-based optical concentrators, and metasails. As the aperture size increases, metalenses admit a larger FOV and could achieve higher numerical apertures (NA), significantly enhancing the imaging quality in low light conditions.

While providing many benefits, upscaling a metasurface footprint comes with a cost. Due to their nanoscale and periodic nature, metasurfaces typically contain millions to billions of meta-atoms, and this number scales quadratically with diameter. For instance, a metasurface with a 1 cm diameter and 310 nm unit cell periodicity, contains roughly one billion meta-atoms. As a result, associating just even one double precision floating point number with each shape already requires several GBs of memory. The quickly growing memory constraints make it challenging to simulate and generate a layout for these extremely large-scale metasurfaces. Beyond that, even if executing the simulation using workaround techniques, such as stitching, is successful, the high amount of aggregate required memory plagues the generation of the layout file needed to fabricate the simulated device.

This layout file generation is a nontrivial aspect of metasurface design and is affected in three fundamental ways by different constraints. First, the total size of the final layout file can easily occupy hundreds of GBs to TBs. This problem has been addressed by converting the final file, which is in graphic design system II (GDSII) binary file format, to newer formats such as open artwork system interchange standard (OASIS) or METAsurface Compression (METAC). The second issue arising during the process is memory bottleneck, in which, even on computers with hundreds of GBs of memory it is challenging to generate a layout file for large-scale metasurfaces due to the extraordinarily high amount of memory required for the layout generation process. For instance, it is not possible to generate the layout file for a 3 mm metasurface with 300 nm unit cell periodicity using the well-known GDSPy library using a PC with 128 GB RAM as this process roughly requires 135 GB of RAM. The third problem arises because even on powerful PCs, layout generation is sequential, making the process incredibly slow.

Therefore, addressing the challenges of large-scale metasurface layout generation necessitates the development of an ultra-fast, parallel, and memory-independent method. To this end, parallel computing has revolutionized numerous research fields, making once intractable computations possible, and reducing running times from days or weeks to just a few minutes. This could provide a promising remedy for the above issues in layout generation. The accessibility of hardware capable parallel computing and the utilization of general-purpose graphics processing units (GPGPUs) have led to significant advancements in areas such as machine learning and artificial intelligence. For instance, GPGPUs have facilitated operations used in artificial neural networks (ANNs).

### ParallelGDS

Disclosed are methods, systems, and computing components for generating a large-scale or unbounded graphic design system II (GDSII) file. In implementations of the disclosed technology, parallel computing techniques are utilized to generate metasurface layout configurations that overcome the aforementioned problems, making it possible to handle the complexities and generate layouts for metasurfaces with large quantities of meta-atoms. The disclosed technique is referred to herein as ParallelGDS.

The disclosed ParallelGDS technology provides a new framework for the fully parallel, ultra-fast, and memory-independent generation of GDSII files for arbitrarily large-scale metasurfaces. The disclosed ParallelGDS framework uses a fixed amount of memory regardless of the size of the metasurface: only 2.7 GB of memory is required for the layout generation of metasurfaces with any arbitrary sizes. Performance of example embodiments of the disclosed ParallelGDS framework has been compared against those of well-known frameworks, such as GDSPy, GDSTK, and GDS export, using LUMERICAL's “polystencil” for gradient and geometrical metasurfaces of different sizes. It has been revealed that the disclosed ParallelGDS framework results in up to 100-fold increase in the generation speeds. Additionally, the framework considerably reduces the amount of required memory with respect to other frameworks by an average factor of approximately 0.50.5×Dₙ² where Dₙ is the normalized metasurface diameter. In the disclosed ParallelGDS framework, an arbitrary adjustment of the required memory and parallelization level, from just using a single core on CPU, to multithread CPU utilization, and finally to the full utilization of all GPU cores for fully parallel layout generation is provided. This enables a user to generate the layout files even on low-end computers with almost any hardware configuration. The disclosed framework paves the way for the layout generation procedure in current and future applications, requiring thin, lightweight, and very large-scale metadevices, such as for next-generation wireless communication technology and advanced computing.

### Example Embodiments of the ParallelGDS Framework

GDSII is a database format for representing planar geometrical shapes and is one of the gold standards in industry for transferring the layouts of integrated circuits. The database comprises hierarchically organized records and uses a binary format for compactness. The coordinates in the format are defined as 4-byte signed integers and stored in big-endian byte order (the most significant byte of a multi-byte data word is stored at the lowest memory address).

Conventionally, the metasurface layout and the corresponding GDSII files are generated using the existing layout creation libraries (e.g., GDSPy, GDSTK, LUMERICAL's Polystencil etc.) in two steps: in the first step, the geometric shape of each meta-atom is created one at a time at the desired position and orientation, e.g., the coordinates of each points forming the shape are calculated. The shapes are kept in the memory until the entire layout is generated. In the second step, the shapes are converted and wrapped into the GDS format and will be saved to the disk.

The conventional approach demonstrates two major drawbacks when generating layouts for large-scale metasurfaces: the first drawback is the sequential nature and running time of the conventional approach; for instance, to create a 3 mm gradient/geometrical metasurface layout with a period of 300 nm, approximately one billion meta-atoms should be created. In each time step, the shape of a single meta-atom is created, and this task needs to be repeated one billion times for the shape generation and one billion times for conversion to the GDSII format. The running time of this method lies in the region of O(n²) as there exists a quadratic relation between the number of meta-atoms and the metasurface size. Therefore, the conventional approach performs significantly slower as the size of the metasurface increases. Converting the generated shapes to the GDS format is done sequentially as well.

The coordinates in GDS format are defined as a 4-byte signed integer and stored in big-endian byte order. The main drawback of this approach is that when working with multi-byte data types, such as integers and floating-point numbers where bitwise operations are required to be performed on the individual bytes, storing data in big-endian format adds an additional conversion process where the data needs to be first converted to little-endian format in CPU. The generated coordinates are scaled and rounded to the nearest integer and converted to the big-endian format afterward which makes the whole process slower and less efficient. Finally, a GDS record is created given the converted coordinates by injecting a record header and footer before and after the coordinate bytes respectively, and the created record is stored on the disk. This approach includes a large number of write-to-disk procedure calls, which further slows down the code.

The second major drawback is the lack of memory management which makes this approach inefficient when dealing with large-scale layouts. In the generation process, the geometric shapes of meta-atoms take some space in the memory as they are created. The shapes are kept in the memory until the entire layout is created. It is only after that the shapes are converted to the desired format and stored on the disk, resulting in a significant memory overhead and processing time. This becomes increasingly challenging as the number of meta-atoms goes from millions to billions, requiring a significant amount of memory to generate the layout.

The disclosed framework, named ParallelGDS, is a new framework designed to efficiently generate GDSII files for large metasurfaces used in various applications, such as wearable devices, lasers, optical sensors, high-resolution microscopy, and virtual or augmented reality. The disclosed ParallelGDS framework can facilitate generation of large-scale metadevices by alleviating memory constraints and minimizing time-consuming processes. The framework provides at least two primary technical advantages: first, optimizing memory efficiency and eliminating hardware restrictions to the greatest extent, and second, significantly reducing the generation time by harnessing the parallelism capabilities of parallel computing devices.

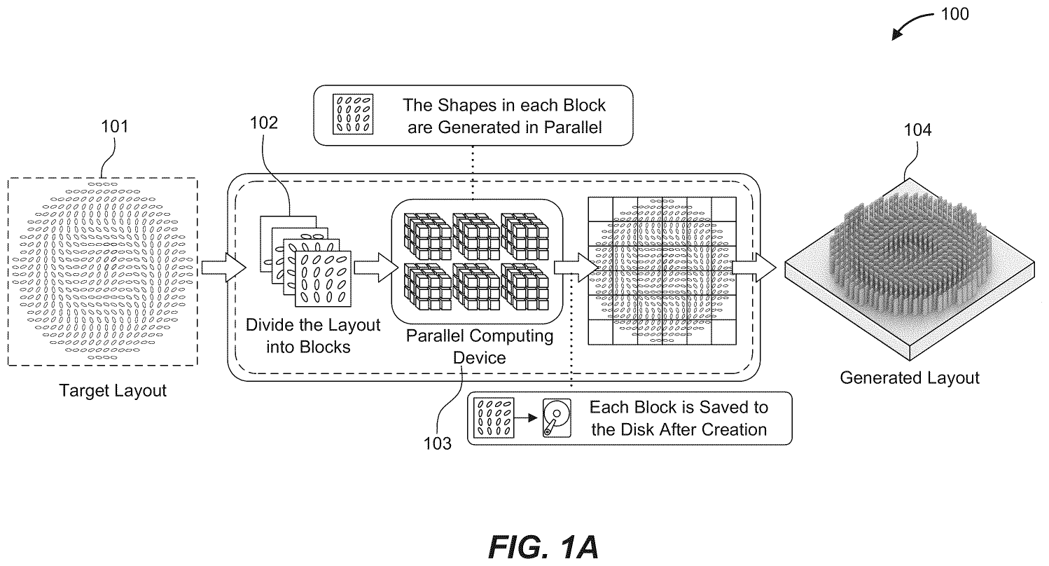

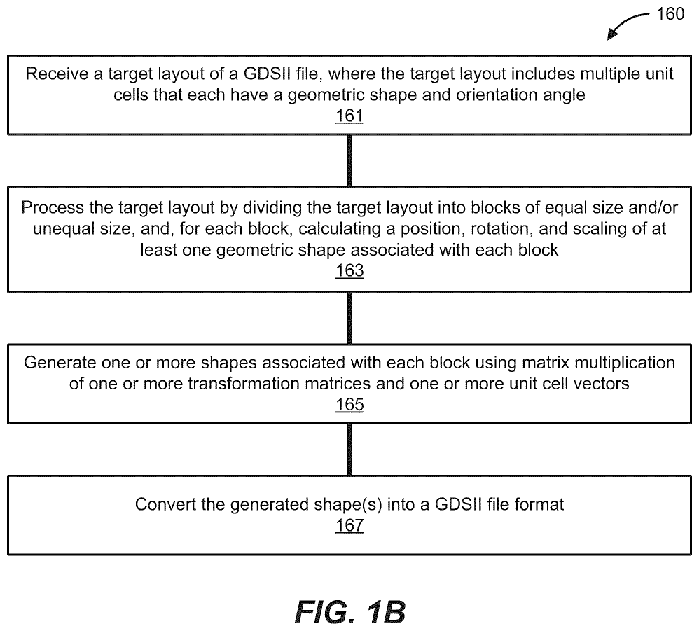

FIG. 1A shows a diagram illustrating an example embodiment of the ParallelGDS framework 100, in accordance with the present technology. The exemplary ParallelGDS framework can achieve memory efficiency by following an approach analogous to divide-and-conquer. For example, instead of generating and storing the entire layout in the memory, converting the layout, and saving the layout afterward, a target layout 101 is generated, converted, and saved in batches of smaller blocks 102 or layouts, as illustrated in FIG. 1A. The blocks 102 are fed to a parallel computing device 103 where all the shapes in each block are generated in parallel. In some embodiments, for example, the parallel computing device 103 (capable of running multiple instructions simultaneously) can include, but is not limited to, CPUs with SIMD capability, general-purpose GPUs, and/or tensor processing units (TPUs). The blocks 102 are saved to a disk after creation, and the blocks 102 combine to form a generated layout 104. Only a fixed amount of memory is needed, regardless of the size of the metasurface.

To reduce the generation time, both generation and graphic design system (GDS) conversion processes are implemented to run on one or more parallel computing devices using single instruction multiple data (SIMD) operations, multi-core and multi-threaded CPUs, or GPUs, resulting in a significant boost in the generation process.

FIG. 1B shows a diagram depicting an example embodiment of a method in accordance with the ParallelGDS framework 100, labeled as method 160. The method includes a process 161 to receive a target layout of a GDSII file, where the target layout includes multiple unit cells that each have a geometric shape and oriented at an angle. The method includes a process 163 to process the target layout by dividing the target layout into blocks of equal size and/or unequal size, and, for each block, calculating the position, rotation, and scaling of at least one geometric shape associated with each block. The method includes a process 165 to generate one or more shapes associated with each block using matrix multiplication of one or more transformation matrices and one or more unit cell vectors. The method includes a process 167 to convert the generated shape(s) into a GDSII file format.

### Example Implementation of a Metasurface Design

Example implementations of the disclosed ParallelGDS framework 100 are described herein that demonstrate the effectiveness and advantages of the disclosed technology. For example, to quantitatively and qualitatively assess the performance of the disclosed framework, two different metasurfaces for the central wavelength of λ₀=650 nm are designed and introduced: a metalens based on gradient phase and a zeroth-order Bessel beam generator based on Pancharatnam-Berry (P.B.) phase.

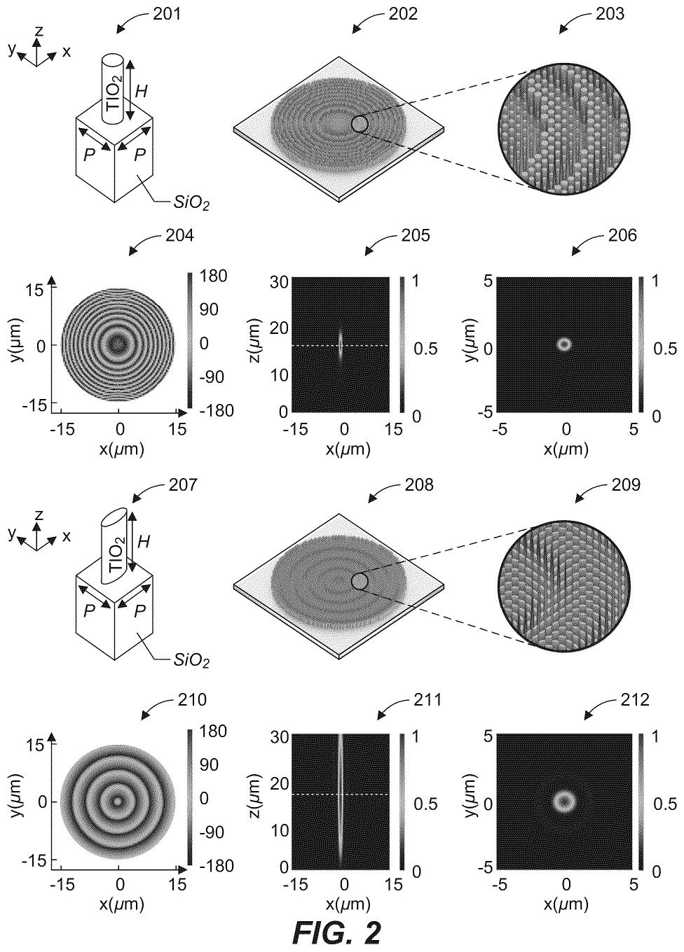

FIG. 2 illustrates various aspects of the two different metasurfaces according to embodiments of the disclosed technology, including a unit cell 201 of the gradient metalens, a 3D-rendered full structure 202 of the gradient metalens, a perspective view 203 of the zoomed-in region of the gradient metalens, the phase 204 of the gradient metalens, the electric field intensity profile in xz-plane 205 of the gradient metalens, and the electric filed intensity profile in xy-plane 206 of the gradient metalens. FIG. 2 also includes a unit cell 207 of the geometrical phase zeroth-order Bessel beam generator, a 3D-rendered full structure 208 of the geometrical zeroth-order Bessel beam generator, a perspective view 209 of the geometrical zeroth-order Bessel beam generator, the phase 210 of the geometrical zeroth-order Bessel beam generator, the electric field intensity profile in xz-plane 211 of the geometrical zeroth-order Bessel beam generator, and the electric field intensity profile in xy-plane of the geometrical zeroth-order Bessel beam generator.

Numerical simulations are performed using Finite-difference Time-domain (FDTD) module of ANSYS LUMERICAL for both unit cell and full-wave simulations of the whole metasurface. The gradient metalens is 30 μm×30 μm and designed to create a focal point at z=15 μm (to mitigate the extremely long simulation times and very large memory requirements. A metalens of 30 μm×30 μm is simulated but the NA of the bigger metalenses remains the same as the designed 30 μm×30 μm metalens). The required phase on the metalens φ(x, y) can be obtained using the following equation:

$$φ ( x , y ) = \frac{2 π}{{λ}_{d}} ( f - \sqrt{{f}^{2} + {x}^{2} + {y}^{2}} )$$

where x and y are points in Cartesian coordinates, λ_{d} is the working wavelength, and f is the focal point of the lens. The optimum values of the geometrical parameters for the unit cells or nanoposts can be found through the sweep of different geometrical parameters using the FDTD module of ANSYS LUMERICAL to achieve the maximum transmission and the required phase for different radii while keeping the height of the nanoposts fixed. Each unit cell includes a cylindrical TiO₂ nanopost (H=600 nm, P=420 nm) on a SiO₂ substrate.

The zeroth-order Bessel beam generator metasurface with NA=0.2 is designed based on geometrical phase using the analytical equation for the transmission of a rotated unit cell:

$$A ( θ ) = ( \begin{matrix}cos θ & - sin θ \\ sin θ & cos θ\end{matrix} ) ( \begin{matrix}{t}_{o} & 0 \\ 0 & {t}_{e}\end{matrix} ) ( \begin{matrix}cos θ & sin θ \\ - sin θ & cos θ\end{matrix} )$$

where tₒ and tₑ represent the complex transmission coefficients when the polarization of incident light is aligned along the principal axes of the meta-atom, and θ is the rotation angle. Considering a circularly-polarized incident light, the transmitted electric field can be mathematically described as:

$${E}_{L / R}^{\text{?}} = \frac{1}{\sqrt{2}} ( \frac{{t}_{o} + {t}_{e}}{2} ) ( \pm {y}_{} ) + \frac{1}{\sqrt{2}} ( \frac{{t}_{o} + {t}_{e}}{2} ) {e}^{i ( \pm 2 θ )} ( ∓ {y}_{} )$$

$$\text{?} \text{indicates text missing or illegible when filed}$$

where, êₓ and ê_{y} are electric field components along x and y-directions. The required phase on the metasurface φ(x, y) can be obtained using:

$$φ ( x , y ) = 2 π ( NA ) ( 1 - \frac{1}{{λ}_{d}} ) \sqrt{{x}^{2} + {y}^{2}} + n {tan}^{- 1} ( \frac{y}{x} )$$

where x and y are points in cartesian coordinates, λ_{d} is the working wavelength, and n is the order of the Bessel beam, where n=0 for the design disclosed. Consequently, rotations of each meta-atom are obtained by θ=φ(x, y)/2. Since each unit cell is a Pancharatnam-Berry optical element (PBOE), PBOEs acts as a half-waveplate and transforms the incident circularly polarized beam to orthogonal polarization. As a result, the geometrical parameters of unit cells need to maximize both transmission and conversion efficiency between the input circular polarization and the orthogonal output polarization. By sweeping different geometrical parameters, the maximum transmission and conversion efficiency is achieved for a unit cell including a TiO₂ nanopost on SiO₂ substrate, with H=600 nm, P=430 nm, Rₓ=75 nm, and R_{y}=180 nm where Rₓ and R_{y} are large and small radii, respectively, of the ellipse shown in the unit cell 207 of FIG. 2.

### The ParallelGDS Framework

The disclosed method tackles the issue of high memory requirements and slow generation times in the following manner. First, to address the excessive memory usage, the large-scale layout is broken down into smaller sub-layouts where only a fraction of the design is generated in each iteration. Second, to speed up the process, the disclosed method reformulates the geometrical shape generation and conversion tasks to run on the parallel computing device, allowing for parallel execution of the entire process. The framework can run either on multicore, multi-thread CPUs, or GPUs. PyTorch is used to implement the main components of the framework due to its excellent parallelism capabilities either on GPU or through heavy utilization of SIMD operations on CPU for data parallelism on hardware level, and due to its optimized parallelism implementations for various tasks including matrix multiplications, vector operations, and convolutions. Additionally, designers can effortlessly define the necessary functions used in the layout generation with PyTorch.

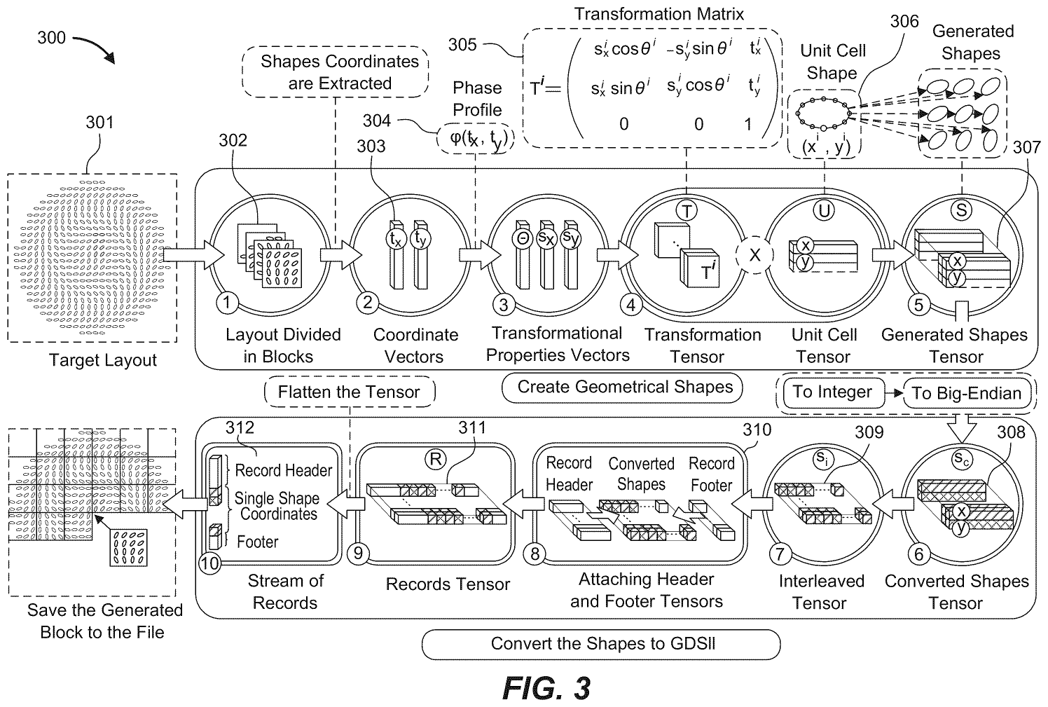

FIG. 3 illustrates a process 300 of generating a large-scale GDSII file using the disclosed ParallelGDS framework. The process 300 comprises two main procedures, first creating geometrical shapes and second converting the geometrical shapes into a GDSII format. The following notations are used: bold lowercase letters denote vectors, bold uppercase letters indicate tensors (matrices are also referred to as second-rank tensors in this text), and plain italic letters to denote scalar quantities. In addition, subscripts indicate specific variables and superscripts indicate scalar elements within the vectors and matrices within the tensors. The entire process of creating the layout is divided into two parts: geometrical shape creation and GDSII format conversion. Considering a target layout for generation, the following steps are performed to create the geometrical shapes:

In the first step, the target layout 301 is divided into an array of blocks 302, each representing a portion of the original layout. The size of the blocks determines how many meta-atoms are generated in parallel; the size is fixed and is defined by the designer. By dividing the layout into blocks 302, only a fraction of the layout is generated and stored on the disk which requires less memory compared to the conventional methods. Consequently, the geometrical shapes in each block are created and converted to the desired format in parallel in the next steps. In the second step, the coordinates of the shapes are extracted in parallel in the form of two vectors 303 of tₓ, t_{y}∈Rⁿ from each block, where n indicates the number of shapes in each block, and R defines the set of real numbers. Finally, given the coordinate vectors tₓ and t_{y}, the transformational properties of the shapes are calculated using the phase profile function 304 in the third step.

This function produces the following vectors: θ, sₓ, s_{y}∈Rₙ where θ is the rotation vector, and sₓ and s_{y} are the scaling vectors in each dimension.

In the fourth step, a 3-D tensor T∈R^{3×3×n} is created by stacking several transformation matrices (Tⁱ) 305 where superscript 0≤i<n denotes the index of the vectors and tensors. A single transformation matrix, which is a composition of scale, rotation, and translation matrices, is defined as follows:

$${T}^{i} = ( \begin{matrix}1 & 0 & {t}_{x}^{i} \\ 0 & 1 & {t}_{y}^{i} \\ 0 & 0 & 1\end{matrix} ) ( \begin{matrix}cos {θ}^{i} & - sin {θ}^{i} & 0 \\ sin {θ}^{i} & cos {θ}^{i} & 0 \\ 0 & 0 & 1\end{matrix} ) ( \begin{matrix}{s}_{x}^{i} & 0 & 0 \\ 0 & {s}_{x}^{i} & 0 \\ 0 & 0 & 1\end{matrix} ) = ( \begin{matrix}{s}_{x}^{i} cos {θ}^{i} & - {s}_{y}^{i} sin {θ}^{i} & {t}_{x}^{i} \\ {s}_{x}^{i} sin {θ}^{i} & {s}_{y}^{i} cos {θ}^{i} & {t}_{y}^{i} \\ 0 & 0 & 1\end{matrix} )$$

The geometrical shape 306 of the unit cell is also defined as a tensor U∈R^{3×m} where the first and second dimensions are the point coordinates, and the third dimension is a vector of ones enabling the translation operation in the transformation matrix and m determines the number of vertices used to create the shape. The unit cell shape can be created within the framework methods or can be manually loaded from a file. The purpose of this step is to map the shape to the desired position, orientation, and form. It should be noted that T can also model shearing, reflection, and in general any mapping that can be expressed as a 3×3 matrix. The transformation tensor is then multiplied by the unit cell tensor, which results in a tensor of generated shapes S∈R^{3×n×m}. The broadcasting feature of PyTorch handles the tensor multiplication with different dimensions, eliminating the need for duplicating the unit cell tensor, making the entire process faster and saving memory. The S tensor 307 includes the generated shapes within the given block 302. Each 2-D slice of S represents a single shape in the block 302.

The following steps demonstrate how the generated shapes are converted to the GDSII format: the augmented dimension of S (i.e., the vector of ones) is discarded and the following operations are performed to the coordinates of S. the numbers are rounded to the nearest integer and their data type is changed from float to integer. Additionally, due to the aforementioned problem regarding mandatory conversion between the little-endian to big-endian, the byte order is converted from little-endian to big-endian. Because a vectorized implementation of the conversion is provided in the disclosed framework, this task can also run in parallel. As a result of the conversion, a new tensor S_{c}∈Z^{2×n×m} 308 is created, where Z denotes the set of integer numbers. Consequently, Sc is interleaved in a way such that the coordinates of each shape are stored consecutively in a single vector; the resulting tensor 309 is Sᵢ∈Z^{n×2m}.

The repetitive process of creating the GDSII records is parallelized by treating the record's header and footer as two numerical tensors. Record's header and footer are fixed-size arrays of bytes that contain information about each record, including type of the record, record's length, and its datatype. In the next step, the byte arrays are converted into the vectors of 4-byte signed integers (compatible with the data type of the coordinates). Finally, the conversions are repeated and attached to the interleaved tensor to simultaneously create all of the records 310 within their shapes. The outcome is a tensor of records 311 R∈Z^{n×(2m+r)}, where r is the length of the attached header and footer. In the final step, the tensor of records R is rearranged to form a single vector and converted to byte data type representing the data stream 312 of the generated block. The resulting data stream 312 is then written to the disk. This iterative process is repeated until all of the blocks are generated. GDSII inherently offers a built-in feature called reference that enables the designers to define and reuse complicated structures or cells throughout the design hierarchy, hence lowering file size and accelerating the layout generation process.

The framework also offers an on-the-fly compression of the output format, with at least 60% reduction in the file size.

### Example Implementations and Results

The disclosed ParallelGDS framework has been employed to produce layouts for gradient and geometric metasurfaces of varying dimensions, previously designed in Section 3. Its performance is assessed in relation to prevalent GDSII generation techniques, namely GDSTk, GDSPy, and LUMERICAL's polystencil. All results were obtained using an identical computer system equipped with 128 GB of memory.

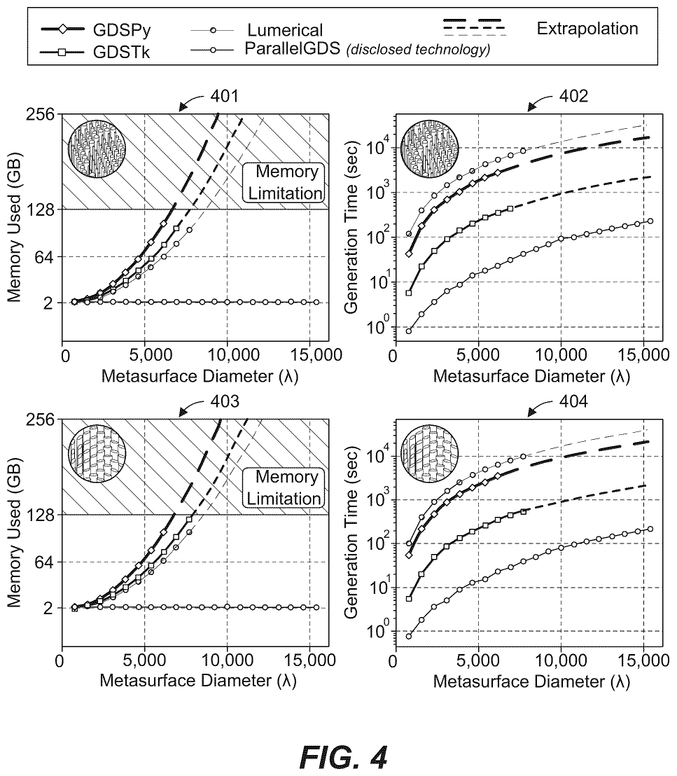

FIG. 4 illustrates comparison of the required memory and generation time of ParallelGDS against GDSPy, GDSPk, and LUMERICAL's polystencil for the gradient metasurface. FIG. 4 also includes comparison of the required memory and generation time of ParallelGDS against GDSPy, GDSPk, and LUMERICAL's polystencil for the geometrical metasurface. As shown in FIG. 4, the disclosed framework demonstrates the ability to generate metasurfaces of arbitrary sizes without encountering any memory constraints. In contrast, alternative methods, such as GDSTK, GDSPy, and LUMERICAL's polystencil, fail to produce layouts for metasurfaces exceeding a threshold. Consequently, data points pertaining to these techniques have been extrapolated in FIG. 4 for metasurface dimensions surpassing a local computer's 128 GB memory limitation. In terms of the required memory, charts 401 and 403 demonstrate that the disclosed framework uses a fixed amount of memory (˜2.7 GB), regardless of the size of the metasurface, which enables generation of metasurfaces of any arbitrarily large size. In contrast, as is evident in charts 401 and 403, the required memory increases rapidly in other methods. A simple polynomial fitting reveals that the disclosed method using ParallelGDS reduces the amount of required memory with respect to other methods by an average factor of 0.50.5×Dₙ² where Dₙ is the normalized metasurface diameter, which is a significant achievement considering the problem is O(n²) complex, e.g., an n-fold increase in the diameter of the metasurface results in n²-fold increase in number of meta-atoms.

As illustrated in charts 402 and 404, the layout generation time for the disclosed framework demonstrates markedly superior performance compared to alternative methods. Notably, the approach using ParallelGDS results in up to two orders of magnitude reduction in generation time for gradient and geometrical metasurfaces. Using the disclosed framework, generating the layout files for any arbitrary metasurface sizes is possible. For example, a layout file for a metasurface with a diameter of 5 cm and unit cell periodicity of 420 nm is attainable.

To examine the influence of vertex count in each shape on generation time and memory requirements for the final layout, the number of vertices constituting each shape has been varied from 10 to 100 in increments of 10. Ten distinct layouts were generated for a 3 mm×3 mm geometrical metasurface with a block size of 128×128.

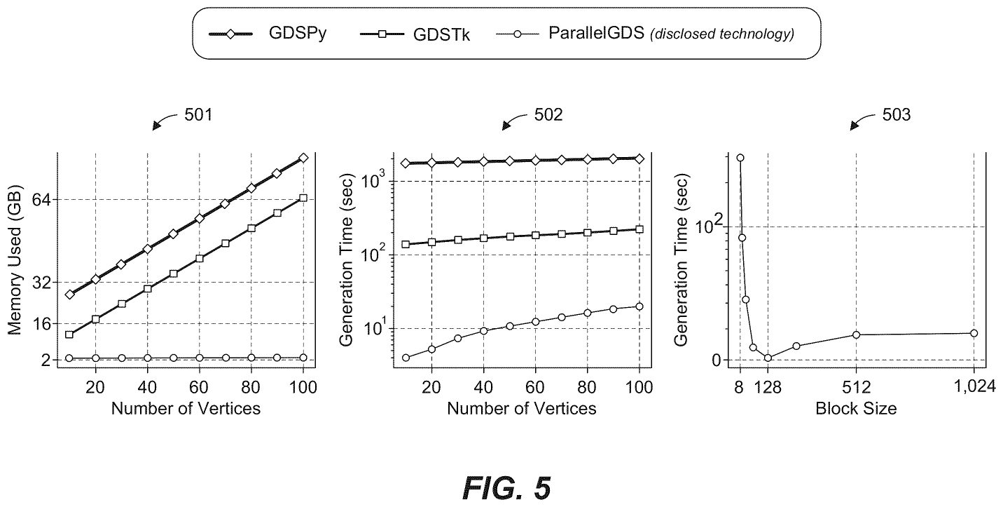

FIG. 5 illustrates comparison of the required memory and generation time against ParallelGDS against GDSPy and GDSTk while varying the number of vertices. FIG. 5 also includes a chart 503 illustrating a block-size experiment in which the optimal block size is determined by generating the same structure while varying the block size. As depicted in charts 501 and 502, increasing the number of vertices does not affect memory utilization of ParallelGDS, whereas GDSPy and GDSTk experience a rapid increase in the amount of required memory as the number of vertices increases. Increasing the number of vertices increases the generation time for all methods, but the generation time for ParallelGDS is far below that of the other two frameworks.

Although the optimal block size is contingent upon various factors including the characteristics of the parallel devices and the nature of the computational tasks at hand, determination of the optimal block size is a critical aspect of achieving maximum performance in any parallel computing system, as it directly impacts the processing capabilities of parallel devices. To investigate the effect of block size on the layout generation time, a 3 mm×3 mm P.B. metasurface where each shape is comprised of 64 vertices is considered. Consequently, to investigate this effect, the block size has been varied from 8 to 1024 with steps in powers of 2. In some implementations, there is a pre-processing step in EBL which is called fracturing where each shape is decomposed or fractured into primitive shapes, such as rectangles and trapezoids for most of the machines. However, since the whole space is raster scanned in EBL machines along the horizontal and vertical directions, every shape, including primitives, has to be fractured to primitives with at least two edges parallel to either horizontal or vertical directions. For the ellipses, because of the round edges, it can be fractured infinite number of times. In some implementations, a pre-fracturing process is used for ellipses, where each ellipse is fractured into odd number of rectangles with their axis aligned with the rotated axis of the ellipse. As depicted in chart 503, increasing the block size results in a significant reduction in generation time up to a critical point. This is due to the enhanced exploitation of parallelism, which allows multiple tasks to be executed simultaneously, thereby increasing the system's overall efficiency. However, after surpassing this critical point which corresponds to the global minimum as shown in chart 503, the generation time rises again. This phenomenon can be explained by the saturation of the parallelism capability of the device, as the increase in block size beyond the critical point no longer contributes to the augmentation of parallelism in the pipeline. As resources become increasingly strained, the parallel devices are unable to sustain further improvements in performance, ultimately leading to diminished efficiency. Considering the current design as an example, the analysis has demonstrated that, the optimal block size is 128×128, which means simultaneously generating 16384 meta-atoms, which results in the fastest processing times, thereby maximizing the potential benefits of the parallel computing system.

To demonstrate adaptivity of the disclosed framework, the performance of the disclosed framework against GDSPy and GDSTk is compared on a low-end computer with 8 GB of memory, and an Intel® Core™ i7-6500U which has two cores and four threads with maximum boost frequency of 3.1 GHz CPU. The test case is a P.B. metasurface with 64 vertices in each shape.

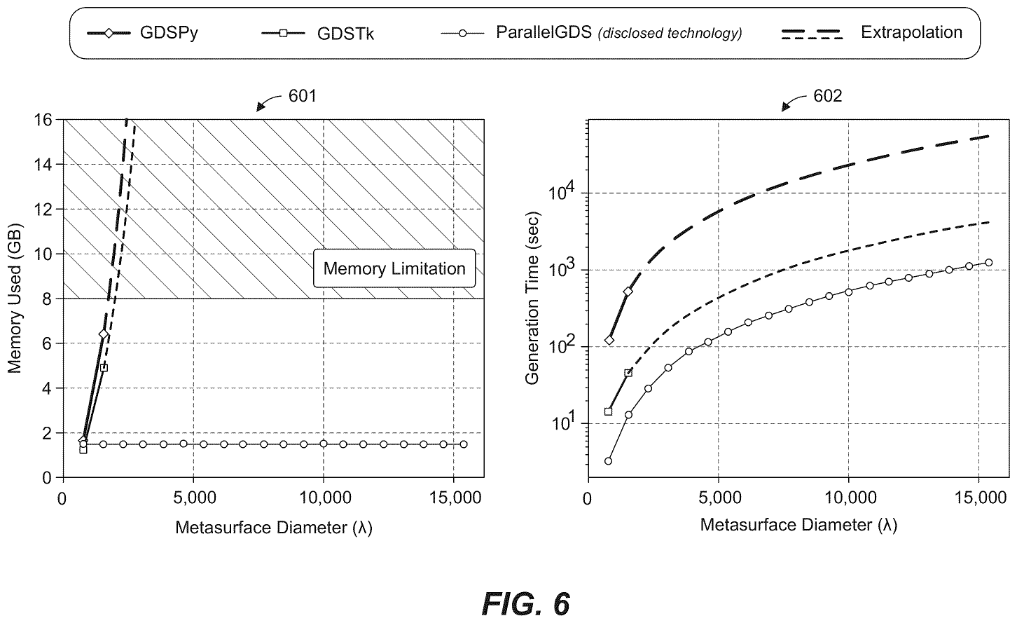

FIG. 6 illustrates the performance comparison of the disclosed framework against GDSPy and GDSTk on a low-end computer. As can be seen in charts 601 and 602, the disclosed framework is able to easily generate metasurfaces of any arbitrary sizes. The only upper limit on the size of the metasurface is the amount of available hard disk space on the machine. In contrast, GDSPy and GDSTk can only generate metasurfaces up to 1 mm. It is essential to highlight the minor difference in memory consumption between the current investigation as shown in FIG. 6 (˜1.5 GB), and the previous experiment presented in FIG. 4, (˜2.7 GB).

The reduction in memory utilization is attributed to the deployment of a low-end machine in the current experiment, in which the GPU is not employed for processing tasks. Instead, all computations are executed by the CPU. As a result, the GPU-related modules, which would typically be initialized upon utilizing the GPU at the beginning of the layout generation process, are rendered unnecessary. Consequently, elimination of these modules results in reduction of the amount of memory required for the successful execution of the experiment.

As shown in the experiments, the disclosed ParallelGDS framework demonstrates a significant advancement in generating GDSII files for large-scale metasurfaces, addressing the critical challenges of slow generation speeds and large memory requirements. Through extensive comparison with existing methods such as GDSTk, GDSPy, and LUMERICAL's polystencil, ParallelGDS showcases remarkable improvements in both speed and memory reduction, with at least 10-fold and up to 100-fold increase in the layout generation speed and a factor of 0.5×Dₙ² in memory requirements where Dₙ is the normalized metasurface diameter. Furthermore, the framework's adaptability in terms of memory usage and parallelization levels enables the framework to cater to a wide range of computational resources. This ranges from single-core CPU usage all the way up to multi-core and multi-threaded CPU utilization, and ultimately to full utilization of all GPU cores, which makes it accessible even on low-end personal computers. ParallelGDS is set to profoundly impact a vast variety of applications requiring thin, lightweight, and very large-scale metasurfaces.

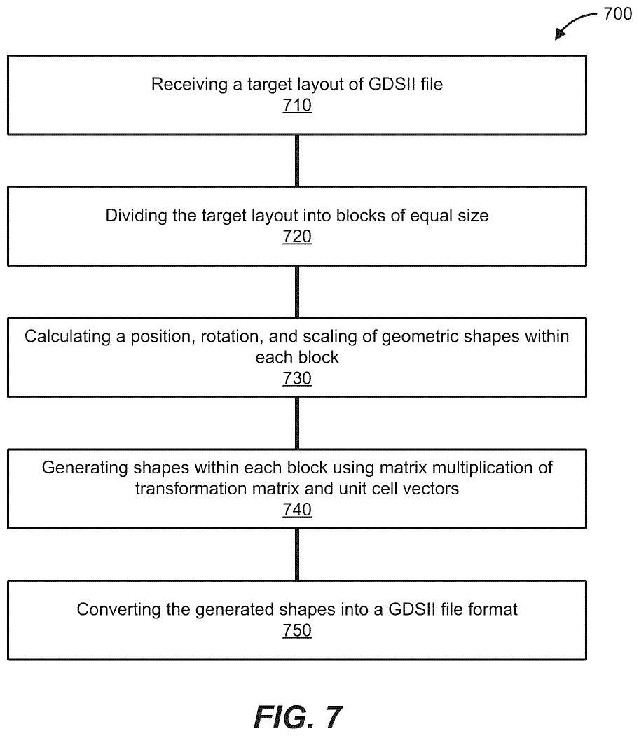

FIG. 7 shows a flowchart representation of an example embodiment of a method for generating a layout using the disclosed ParallelGDS framework. The method 700 includes, at operation 710, receiving a target layout of a GDSII file, wherein the target layout includes multiple unit cells that each have a geometric shape and oriented at an angle. The method 700 includes, at operation 720, upon receiving the target layout, dividing the target layout into blocks of equal size. The method 700 includes, at operation 730, calculating a position, rotation, and scaling of the geometric shapes within each block. The method 700 includes, at operation 740, generating shapes within each block using matrix multiplication of transformation matrix and unit cell vectors. The method 700 includes, at operation 750, converting the generated shapes into a GDSII file format.

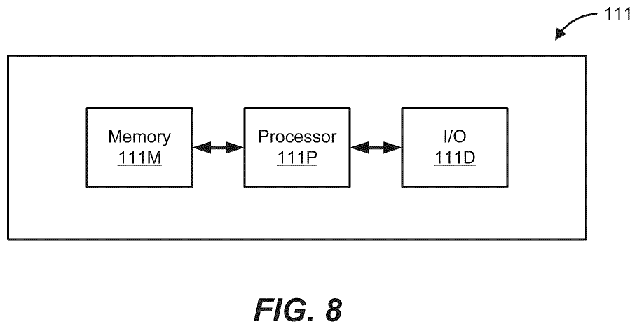

FIG. 8 shows a diagram of an example embodiment of a data processing unit 111 of a computer device operable to implement the disclosed methods, computer program products, and computing products in accordance with the present technology. The data processing unit 111 can include a processor 111P that can be in communication with a memory 111M and an input/output (I/O) unit 111D. To support various functions of the data processing unit 111, the processor 111P can be included to interface with and control operations of other components of the data processing unit 111, such as the I/O unit 111D and/or the memory 111M. In some embodiments of the data processing unit 111, for example, the processor 111P can include a central processing unit (CPU) and/or a graphic processing unit (GPU), e.g., such as general-purpose graphics processing units (GPGPUs), and/or various combination of one or more CPUs and/or GPUs. The memory 111M can store information and data, e.g., such as instructions, software, values, images, and other data processed or referenced by the processor 111P. Various types of Random Access Memory (RAM) devices, Read Only Memory (ROM) devices, Flash Memory devices, and other suitable storage media can be used to implement storage functions of the memory 111M. The memory 111M can store data and information, e.g., which can be used to implement various systems and/or various methods in accordance with the disclosed ParallelGDS framework. The I/O unit 111D can be connected to an external interface, source of data storage, or display device. Various types of wired or wireless interfaces compatible with typical data communication standards can be used in communications of the data processing unit 111 and/or other units of a computer device, e.g., including, but not limited to, Universal Serial Bus (USB), IEEE 1394 (FireWire), Bluetooth, Bluetooth Low Energy (BLE), ZigBee, IEEE 802.111, Wireless Local Area Network (WLAN), Wireless Personal Area Network (WPAN), Wireless Wide Area Network (WWAN), WiMAX, IEEE 802.16 (Worldwide Interoperability for Microwave Access (WiMAX)), 3G/4G/LTE/5G/6G cellular communication methods, and parallel interfaces, can be used to implement the I/O unit 111D. The I/O unit 111D can interface with an external interface, source of data storage, or display device to retrieve and transfer data and information that can be processed by the processor 111P, stored in the memory 111M, or exhibited on a display unit.

### EXAMPLES

In some embodiments in accordance with the present technology (example 1), a computer-implemented method for generating an unbounded graphic design system II (GDSII) file includes receiving, at a computing device comprising a processor and a memory, a target layout of a GDSII file, wherein the target layout includes multiple unit cells that each have a geometric shape and oriented at an angle; upon receiving the target layout, dividing the target layout into blocks of one or both of equal size and unequal size; for each block, calculating a position, rotation, and scaling of at least one geometric shape associated with each block; generating one or more shapes associated with each block using matrix multiplication of one or more transformation matrices and one or more unit cell vectors; and converting the generated one or more shapes into a GDSII file format.

Example 2 includes the method of example 1 or any of examples 1-13, wherein the computer-implemented method is implementable by the computing device using 2.7 GB or less of the memory of the computing device.

Example 3 includes the method of example 1 or any of examples 1-13, wherein the GDSII file format represents a metasurface layout for a metasurface having an array of nanostructures corresponding to one or more meta-atoms.

Example 4 includes the method of example 3 or any of examples 1-13, wherein the one or more meta-atoms in the metasurface layout are indicative of optical properties of a designed material.

Example 5 includes the method of example 1 or any of examples 1-13, wherein the computer-implemented method is operable to reduce an amount of required computer memory for implementation of the method by an average factor of approximately 0.5×Dₙ², where Dₙ is a normalized metasurface diameter.

Example 6 includes the method of example 1 or any of examples 1-13, wherein a first unit cell and a second unit cell of the multiple unit cells of the target layout are configured to have one or more of: (i) a same shape and a same size among the first unit cell and the second unit cell, (ii) a same shape and a same angle of orientation among the first unit cell and the second unit cell, (iii) a same shape and a different size among the first unit cell and the second unit cell, (iv) a same shape and different angle of orientation among the first unit cell and the second unit cell, (v) a different size and a same shape among the first unit cell and the second unit cell, (vi) a different size and a same angle of orientation among the first unit cell and the second unit cell, (vii) a different size and a different shape among the first unit cell and the second unit cell, or (viii) a different size and a different angle of orientation among the first unit cell and the second unit cell.

Example 7 includes the method of example 1 or any of examples 1-13, wherein the generating of the one or more shapes associated with each block are generated in parallel.

Example 8 includes the method of example 1 or any of examples 1-13, wherein the converting the generated one or more shapes into the GDSII file format includes combining the blocks to form a design layout.

Example 9 includes the method of example 8 or any of examples 1-13, wherein the formed design layout corresponds to a metasurface of a metamaterial.

Example 10 includes the method of example 1 or any of examples 1-13, further comprising processing the target layout that includes the multiple unit cells by configuring at least some of unit cells into a plurality of layers of the at least some unit cells.

Example 11 includes the method of example 10 or any of examples 1-13, wherein the plurality of layers corresponds to at least one particle of a metasurface for a metamaterial.

Example 12 includes the method of example 1 or any of examples 1-13, wherein the processor of the computer includes a multicore, multi-thread central processing unit (CPU) or a graphics processing unit (GPU).

Example 13 includes the method of example 1 or any of examples 1-13, wherein the computing device is a parallel computing device.

In some embodiments in accordance with the present technology (example 14), an engineered metamaterial designed using a graphic design system II (GDSII) file, wherein the GDSII file used to design the engineered metamaterial was generated by a method, comprising receiving, at a computing device comprising a processor and a memory, a target layout of a GDSII file, wherein the target layout includes multiple unit cells that each have a geometric shape and oriented at an angle; upon receiving the target layout, dividing the target layout into blocks of one or both of equal size and unequal size; for each block, calculating a position, rotation, and scaling of at least one geometric shape associated with each block; generating one or more shapes associated with each block using matrix multiplication of one or more transformation matrices and one or more unit cell vectors; and converting the generated one or more shapes into a GDSII file format.

Example 15A includes the engineered metamaterial of example 14, wherein the metamaterial is part of a metadevice including one or more of a metalense, a structured light projector, a beam splitter, a beam combiner, a meta-power-limiter, a carpet cloaking device, a hologram generator, or a sensor using both dielectric and plasmonic metasurfaces.

Example 15B includes the engineered metamaterial of example 14 or example 15, wherein the method used to generate the design of the engineered metamaterial includes one or more features of the method of any of examples 1-13.

In some embodiments in accordance with the present technology (example 16), a non-transitory, computer-readable medium storing instructions thereon that, when executed by one or more processors of a computing system, cause the computing system to perform operations for generating an unbounded graphic design system II (GDSII) file, where the operations comprise: receiving, at the computing system, a target layout of a GDSII file, wherein the target layout includes multiple unit cells that each have a geometric shape and oriented at an angle; upon receiving the target layout, dividing the target layout into blocks of one or both of equal size and unequal size; for each block, calculating a position, rotation, and scaling of at least one geometric shape associated with each block; generating one or more shapes associated with each block using matrix multiplication of one or more transformation matrices and one or more unit cell vectors; and converting the generated one or more shapes into a GDSII file format.

Example 17 includes the non-transitory, computer-readable medium of example 16 or any of examples 16-21, wherein the instructions are executable on the computer system using 2.7 GB or less of computer memory of the computing system.

Example 18 includes the non-transitory, computer-readable medium of example 16 or any of examples 16-21, wherein the computing system, when the instructions are executed by the one or more processors, is operable to reduce an amount of required computer memory when performing the operations by an average factor of approximately 0.5×Dₙ², where Dₙ is a normalized metasurface diameter.

Example 19 includes the non-transitory, computer-readable medium of example 16 or any of examples 16-21, wherein the converting the generated one or more shapes into the GDSII file format includes combining the blocks to form a design layout.

Example 20 includes the non-transitory, computer-readable medium of example 16 or any of examples 16-21, wherein the operations further comprise processing the target layout that includes the multiple unit cells by configuring at least some of unit cells into a plurality of layers of the at least some unit cells.

Example 21 includes the non-transitory, computer-readable medium of example 16 or any of examples 16-20, wherein the operations performed to generate the GDSII file includes one or more features of the method of any of examples 1-13.

### CONCLUSION

Implementations of the subject matter and the functional operations described in this patent document can be implemented in various systems, digital electronic circuitry, or in computer software, firmware, or hardware, including the structures disclosed in this specification and their structural equivalents, or in combinations of one or more of them. Implementations of the subject matter described in this specification can be implemented as one or more computer program products, i.e., one or more modules of computer program instructions encoded on a tangible and non-transitory computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of nonvolatile memory, media and memory devices, including by way of example semiconductor memory devices, e.g., EPROM, EEPROM, and flash memory devices. The processor and the memory can be supplemented by, or incorporated in, special purpose logic circuitry.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described, and other implementations, enhancements and variations can be made based on what is described and illustrated in this patent document.

What is claimed is:

1. A computer-implemented method for generating an unbounded graphic design system II (GDSII) file, the method comprising:
receiving, at a computing device comprising a processor and a memory, a target layout of a GDSII file, wherein the target layout includes multiple unit cells that each have a geometric shape and oriented at an angle;
upon receiving the target layout, dividing the target layout into blocks of one or both of equal size and unequal size;
for each block, calculating a position, rotation, and scaling of at least one geometric shape associated with each block;
generating one or more shapes associated with each block using matrix multiplication of one or more transformation matrices and one or more unit cell vectors; and
converting the generated one or more shapes into a GDSII file format.

2. The method of claim 1, wherein the computer-implemented method is implementable by the computing device using 2.7 GB or less of the memory of the computing device.

3. The method of claim 1, wherein the GDSII file format represents a metasurface layout for a metasurface having an array of nanostructures corresponding to one or more meta-atoms.

4. The method of claim 3, wherein the one or more meta-atoms in the metasurface layout are indicative of optical properties of a designed material.

5. The method of claim 1, wherein the computer-implemented method is operable to reduce an amount of required computer memory for implementation of the method by an average factor of approximately 0.5×Dₙ², where Dₙ is a normalized metasurface diameter.

6. The method of claim 1, wherein a first unit cell and a second unit cell of the multiple unit cells of the target layout are configured to have one or more of: (i) a same shape and a same size among the first unit cell and the second unit cell, (ii) a same shape and a same angle of orientation among the first unit cell and the second unit cell, (iii) a same shape and a different size among the first unit cell and the second unit cell, (iv) a same shape and different angle of orientation among the first unit cell and the second unit cell, (v) a different size and a same shape among the first unit cell and the second unit cell, (vi) a different size and a same angle of orientation among the first unit cell and the second unit cell, (vii) a different size and a different shape among the first unit cell and the second unit cell, or (viii) a different size and a different angle of orientation among the first unit cell and the second unit cell.

7. The method of claim 1, wherein the generating of the one or more shapes associated with each block are generated in parallel.

8. The method of claim 1, wherein the converting the generated one or more shapes into the GDSII file format includes combining the blocks to form a design layout.

9. The method of claim 8, wherein the formed design layout corresponds to a metasurface of a metamaterial.

10. The method of claim 1, further comprising:
processing the target layout that includes the multiple unit cells by configuring at least some of unit cells into a plurality of layers of the at least some unit cells.

11. The method of claim 10, wherein the plurality of layers corresponds to at least one particle of a metasurface for a metamaterial.

12. The method of claim 1, wherein the processor of the computer includes a multicore, multi-thread central processing unit (CPU) or a graphics processing unit (GPU).

13. The method of claim 1, wherein the computing device is a parallel computing device.

14. An engineered metamaterial designed using a graphic design system II (GDSII) file, wherein the GDSII file used to design the engineered metamaterial was generated by a method comprising:
receiving, at a computing device comprising a processor and a memory, a target layout of a GDSII file, wherein the target layout includes multiple unit cells that each have a geometric shape and oriented at an angle;
upon receiving the target layout, dividing the target layout into blocks of one or both of equal size and unequal size;
for each block, calculating a position, rotation, and scaling of at least one geometric shape associated with each block;
generating one or more shapes associated with each block using matrix multiplication of one or more transformation matrices and one or more unit cell vectors; and
converting the generated one or more shapes into a GDSII file format.

15. The engineered metamaterial of claim 14, wherein the metamaterial is part of a metadevice including one or more of a metalense, a structured light projector, a beam splitter, a beam combiner, a meta-power-limiter, a carpet cloaking device, a hologram generator, or a sensor using both dielectric and plasmonic metasurfaces.

16. A non-transitory, computer-readable medium storing instructions thereon that, when executed by one or more processors of a computing system, cause the computing system to perform operations for generating an unbounded graphic design system II (GDSII) file, the operations comprising:
receiving, at the computing system, a target layout of a GDSII file, wherein the target layout includes multiple unit cells that each have a geometric shape and oriented at an angle;
upon receiving the target layout, dividing the target layout into blocks of one or both of equal size and unequal size;
for each block, calculating a position, rotation, and scaling of at least one geometric shape associated with each block;
generating one or more shapes associated with each block using matrix multiplication of one or more transformation matrices and one or more unit cell vectors; and
converting the generated one or more shapes into a GDSII file format.

17. The non-transitory, computer-readable medium of claim 16, wherein the instructions are executable on the computer system using 2.7 GB or less of computer memory of the computing system.

18. The non-transitory, computer-readable medium of claim 16, wherein the computing system, when the instructions are executed by the one or more processors, is operable to reduce an amount of required computer memory when performing the operations by an average factor of approximately 0.5×Dₙ², where Dₙ is a normalized metasurface diameter.

19. The non-transitory, computer-readable medium of claim 16, wherein the converting the generated one or more shapes into the GDSII file format includes combining the blocks to form a design layout.

20. The non-transitory, computer-readable medium of claim 16, wherein the operations further comprise:
processing the target layout that includes the multiple unit cells by configuring at least some of unit cells into a plurality of layers of the at least some unit cells.
